(19) United States
(12) Patent Application Publication
(10) Pub. No.: US 2017/0112025 A1
(43) Pub. Date: Apr. 20, 2017

(54) COOLING SYSTEM OF DATA CENTER

(71) Applicant: HON HAI PRECISION INDUSTRY CO., LTD., New Taipei (TW)

(72) Inventors: TZE-CHERN MAO, New Taipei (TW); CHIH-HUNG CHANG, New Taipei (TW); YEN-CHUN FU, New Taipei (TW); YAO-TING CHANG, New Taipei (TW); CHAO-KE WEI, New Taipei (TW); HUNG-CHOU CHAN, New Taipei (TW)

(21) Appl. No.: 14/972,476

(22) Filed: Dec. 17, 2015

(30) Foreign Application Priority Data
Oct. 16, 2015 (CN) 201510667673.7

(51) Int. Cl. H05K 7/20; G06F 1/20

(52) U.S. Cl. CPC H05K 7/20836; H05K 7/20718; G06F 1/206

(57) ABSTRACT

A cooling system for a data center includes a cooling module and at least one heating module. The cooling module includes at least one cooling device and at least one airflow control switch. An air inlet is defined in the cooling module. The at least one heating module includes a heating device. When hot air flows into the air inlet, the at least one airflow control switch is closed, the hot air is cooled by the cooling device and passes through the heating device to cool the heating device. When cool air flows into the air inlet, the at least one airflow control switch is open, the cool air passes through the at least one airflow control switch and the heating device to cool the heating device.

### CROSS-REFERENCE TO RELATED APPLICATIONS

This application claims priority to Chinese Patent Application No. 201510667673.7 filed on Oct. 16, 2015, the contents of which are incorporated by reference herein.

### FIELD

The subject matter herein generally relates to cooling systems.

### BACKGROUND

A data center typically includes a number of servers. When a number of servers work, lots of heat will be produced. So the data center also needs a cooling system for dissipating heat generated by the servers.

### BRIEF DESCRIPTION OF THE DRAWINGS

Implementations of the present technology will now be described, by way of example only, with reference to the attached figures.

FIG. 1 is a diagrammatic view of a first embodiment of a cooling system of data center.

FIG. 2 is a diagrammatic view of a second embodiment of a cooling system of data center.

FIG. 3 is a diagrammatic view of a third embodiment of a cooling system of data center.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

The present disclosure is described in relation to a cooling system applied to data center. A cooling system of data center includes a cooling module and at least one heating module. The cooling module includes at least one cooling device and at least one air control switch. An air inlet is defined in the cooling module. The at least one heating module includes a heating device. When hot air flows into the air inlet, the at least one air control switch is closed and the hot air is cooled by the cooling device, to pass through the heating device to cool the heating device. When cool air flows into the air inlet, the at least one air control switch is open, the cool air passes through the at least one air control switch and through the heating device to cool the heating device.

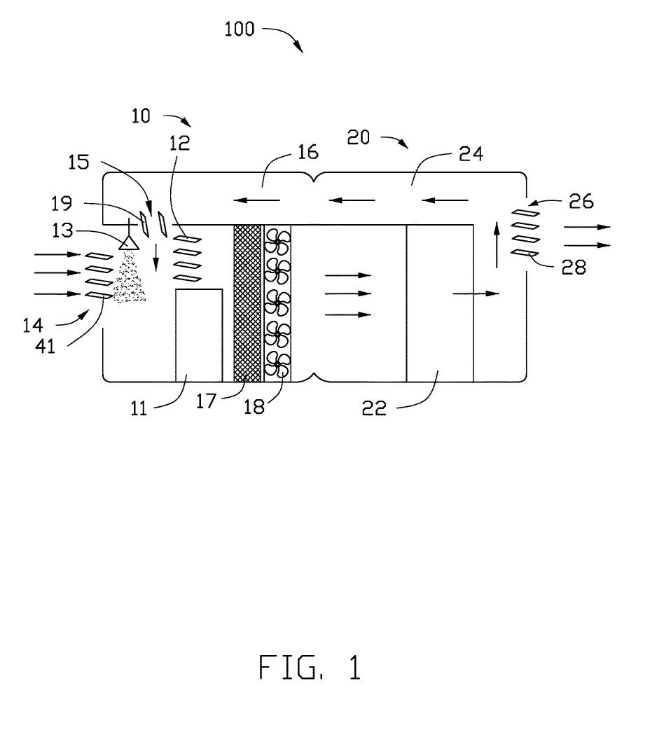

FIG. 1 illustrates a first embodiment of a cooling system of data center 100. The cooling system of data center 100 includes a cooling module 10 and a heating module 20.

The cooling module 10 includes a cooling device 11, two air control switches 12 and 19, a humidity control device 13, a filtering device 17, and a plurality of fans 18. The cooling module 10 defines an air inlet 14, a cutout 15, and a first channel 16. The cooling device 11 and the air control switch 12 can be aligned in a straight line. The humidity control device 13 is located between the air inlet 14 and the air control switch 12. The cutout 15 is connected to the first channel 16. The air control switch 19 is located in the cutout 15. The plurality of fans 18 can be aligned in a straight line. The filtering device 17 is located between the cooling device 11 and the plurality of fans 18.

The heating module 20 includes a heating device 22 and defines a second channel 24 and an air outlet 26. An air control switch 28 is located in the air outlet 26. The first channel 16 is connected to the second channel 24. The cooling system of data center 100 further includes an inductor (not shown) or other sensor. The inductor can sense and value an ambient temperature outside the data center 100. The temperature value is transmitted to a control center (not shown). When the temperature outside is greater than a temperature of the cooling system of data center 100, the inductor sends a first signal to control center to close the air control switch 12. When the temperature outside is less than the temperature of the cooling system of data center 100, the inductor sends a second signal to control center to open the air control switch 12.

When a temperature of the air is below 18 degrees, the air control switch 41, the air control switch 12, the air control switch 19 and the air control switch 28 are proportionally open. The air passes through the air control switch 12 and the filtering device 17. The air is transmitted to the heating device 22 by the plurality of fans 18 to cool the heating device 22. A part of the air from the heating device 22 flows out of the cooling system of data center 100 via the air outlet 26. The remainder of the air from the heating device 22 passes through the second channel 24 and the first channel 16, then flows into the cooling module 10 via the cutout 15. The air from the heating device 22 is mixed with the cold air from the air inlet 14 to let the air temperature before feeding the heating device 22 is suitable for heating device 22 working. The air control switch 41 can control how much air could rush into the cooling module 10 from the air inlet 14. The air control switch 28 can control how much air could rush out of the heating module 20 from the air outlet 26. The control switch 19 can control how much air could rush into the cooling module 10 from the cutout 15.

When the temperature of the air is between 27 degrees and 18 degrees, the air control switch 41, the air control switch 12 and the air control switch 28 are open. The air passes through the air control switch 12 and the filtering device 17. The air is transmitted to the heating device 22 by the plurality of fans 18 to cool the heating device 22. The air from the heating device 22 flows out of the cooling system of data center 100 via the air outlet 26.

When the temperature of the air is between 30 degrees and 27 degrees, the air control switch 41, and the air control switch 28 are open. The air control switch 12 is closed. The air is cooled by the cooling device 11 and then passes through the filtering device 17 to clean the air. The air is transmitted to the heating device 22 by the plurality of fans 18 to cool the heating device 22. The air from the heating device 22 flows out of the cooling system of data center 100 via the air outlet 26.

When the temperature of the air is above 30 degrees, the air control switch 41, the air control switch 12, and the air control switch 28 are closed. The air is cooled by the cooling device 11 and then passes through the filtering device 17 to clean the air. The air is transmitted to the heating device 22 by the plurality of fans 18 to cool the heating device 22. The air from the heating device 22 passes through the second channel 24 and the first channel 16, then flows into the cooling module 10 via the cutout 15.

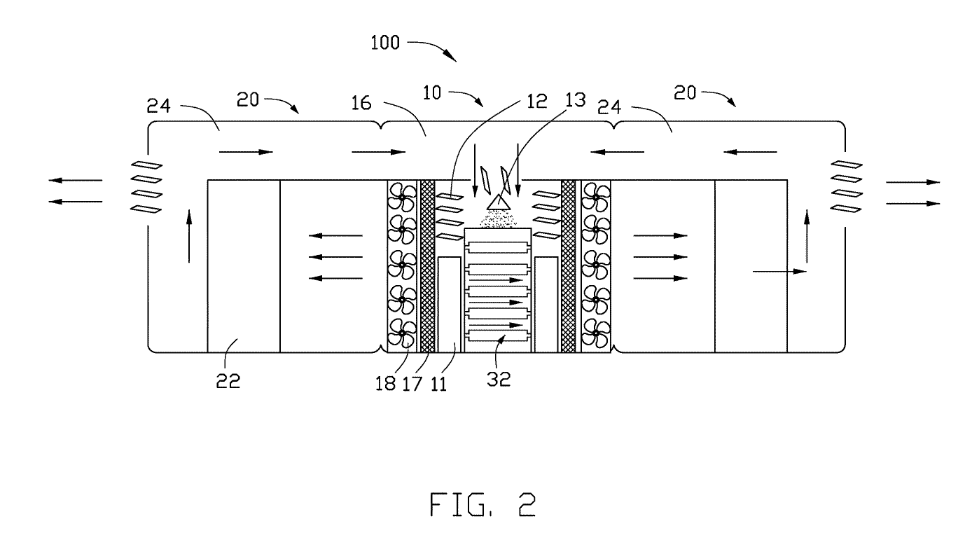

FIG. 2 illustrates a second embodiment of a cooling system of data center 100. The cooling system of data center 100 includes a cooling module 10 and two heating modules 20. The cooling module 10 defines an air inlet 32. The cooling module 10 includes a cooling device 11 located on one side of the air inlet 32, an air control switch 12, a filtering device 17, and a plurality of fans 18. The cooling device 11 and the air control switch 12 can be aligned in a straight line. A cooling device 11, an air control switch 12, a filtering device 17, and a plurality of fans 18 are mounted on other side of the air inlet 32. The second channel 24 of each heating module 20 is connected to the first channel 16 of the cooling module 10.

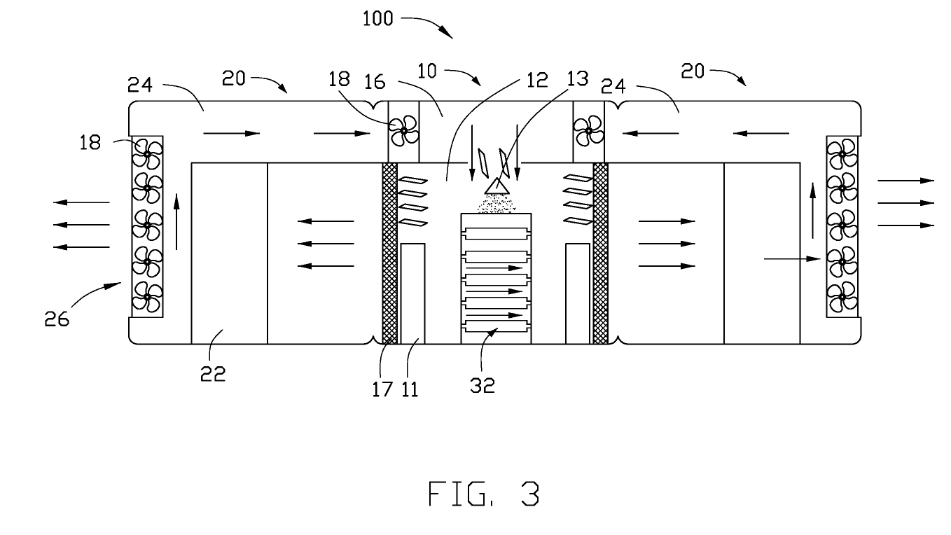

FIG. 3 illustrates a third embodiment of a cooling system of data center 100. The cooling system of data center 100 includes a cooling module 10 and two heating modules 20. A plurality of fans 18 is located in the air outlet 26. A fan 18 is located on a junction of the first channel 16 and the second channel 24.

The embodiments shown and described above are only examples. Many details are often found in the art such as the other features of the cooling system of data center. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A cooling system of data center comprising:
a cooling module defining an air inlet and comprising at least one cooling device and at least one air control switch; and
at least one heating module comprising a heating device;
wherein the at least one air control switch having a closed position, in which the air inlet receiving a hot hair for the hot hair being cooled by the cooling device and passes through the heating device to cool the heating device and an opening position, in which the air inlet receiving a cool hair for the cool hair being passed through the at least one air control switch and the heating device to cool the heating device.

2. The cooling system of data center of claim 1, wherein the cooling module further comprise a humidity control device and an inductor, the humidity control device is located between the air inlet and the air control switch to adjust air humidity, when the temperature of outdoors is greater than a temperature of the cooling system of data center, the inductor sends a first signal to a control center to close the air control switch; and when the temperature of outdoors is less than the temperature of the cooling system of data center, the inductor sends a second signal to the control center to open the air control switch.

3. The cooling system of data center of claim 1, wherein the cooling module defines a cutout and a first channel, the at least one heating module defines a second channel and an air outlet, the first channel is connected to the second channel, the part of the air from the heating device flows out of the cooling system of data center via the air outlet, the rest of the air from the heating device passes through the second channel and the first channel, and is mixed with the hot air from the air inlet via the cutout.

4. The cooling system of data center of claim 3, wherein the outlet is connected to the first channel, and an air control switch is located in the outlet.

5. The cooling system of data center of claim 4, wherein the at least one heating module comprise two heating modules, the cooling module is between the two heating modules, the first channel of the cooling module is connected to the second channel of each heating module, and a cooling device and an air control switch are located on each side of the cooling device.

6. The cooling system of data center of claim 5, wherein a fan is located on a junction of the first channel and the second channel.

7. The cooling system of data center of claim 5, wherein a plurality of fans is located in the air outlet.

8. The cooling system of data center of claim 5, wherein an air control switch is located in the air outlet.

9. The cooling system of data center of claim 1, wherein the cooling module further comprises a filtering device, the filtering device is located between the air control switch and the heating device, and the air from air inlet passes through the filtering device to the heating device.

10. The cooling system of data center of claim 9, wherein the cooling module further comprises a plurality of fans, the plurality of fans is located between the filtering device and the heating device.

11. A cooling system of data center comprising:
two heating modules, each heating module comprising a heating device; and
a cooling module being located between the two heating modules, the cooling module being connected with each heating module, the cooling module comprising at least one cooling device and at least one air control switch, and the cooling module defining an air inlet;
wherein the at least one air control switch having a closed position, in which the air inlet receiving a hot hair for the hot hair being cooled by the cooling device and passes through the heating device to cool the heating device and an opening position, in which the air inlet receiving a cool hair for the cool hair being passed through the at least one air control switch and the heating device to cool the heating device.

12. The cooling system of data center of claim 11, wherein the cooling module further comprise a humidity control device and an inductor, the humidity control device is located between the air inlet and the air control switch to adjust air humidity, when the temperature of outdoors is greater than a temperature of the cooling system of data center, the inductor sends a first signal to a control center to close the air control switch; and when the temperature of outdoors is less than the temperature of the cooling system of data center, the inductor sends a second signal to the control center to open the air control switch.

13. The cooling system of data center of claim 11, wherein the cooling module defines a cutout and a first channel, each heating module defines a second channel and an air outlet, the first channel is connected to the second channel, the part of the air from the heating device flows out of the cooling system of data center via the air outlet, the rest of the air from the heating device passes through the second channel and the first channel, and is mixed with the hot air from the air inlet via the cutout.

14. The cooling system of data center of claim 13, wherein the outlet is connected to the first channel, and an air control switch is located in the outlet.

15. The cooling system of data center of claim 14, wherein a fan is located on a junction of the first channel and the second channel.

16. The cooling system of data center of claim 14, wherein a plurality of fans is located in the air outlet.

17. The cooling system of data center of claim 14, wherein an air control switch is located in the air outlet.

18. The cooling system of data center of claim 11, wherein the cooling module further comprises a filtering device, the filtering device is located between the air control switch and the heating device, and the air from air inlet passes through the filtering device to the heating device.

19. The cooling system of data center of claim 18, wherein the cooling module further comprises a plurality of fans, the plurality of fans is located between the filtering device and the heating device.
